(19) United States
(12) Patent Application Publication
(10) Pub. No.: US 2024/0429920 A1
(43) Pub. Date: Dec. 26, 2024

(54) FPGA AND FPGA SYSTEM

(71) Applicant: Nippon Telegraph and Telephone Corporation, Tokyo (JP)

(72) Inventors: Kenji Tanaka, Tokyo (JP); Yuki Arikawa, Tokyo (JP); Tsuyoshi Ito, Tokyo (JP); Takeshi Sakamoto, Tokyo (JP)

(21) Appl. No.: 18/684,807

(22) PCT Filed: Aug. 31, 2021
(86) PCT No.: PCT/JP2021/031861

§ 371 Date: Feb. 19, 2024

(51) Int. Cl. H03K 19/17728; H03K 19/1776

(52) U.S. Cl. CPC H03K 19/17728; H03K 19/1776

(57) ABSTRACT

An FPGA includes a reconfigurable circuit region, an access acceptance unit that transfers data to be processed included in a function use request from a client to a function circuit constructed in the circuit region and returns a processing result to the client, and a function token table in which a function ID that is identification information for each portion of the circuit region, a function name representing a function of the function circuit, and a token that is identification information of the function circuit are stored in association with each other.

### CROSS-REFERENCE TO RELATED APPLICATIONS

This patent application is a national phase entry of PCT Application No. PCT/JP2021/031861, filed on Aug. 31, 2021, which application is hereby incorporated herein by reference.

### TECHNICAL FIELD

The present invention relates to a field programmable gate array (FPGA) and an FPGA system that performs data processing using the FPGA.

### BACKGROUND

In a conventional data center, central processing unit (CPU)-centered architecture has been adopted. However, in recent years, since performance improvement of a CPU has slowed down, a data center including an accelerator other than a CPU has appeared in order to meet a performance requirement of an application. Among them, an accelerator called a field programmable gate array (FPGA) attracts attention from the viewpoint of (I) having a characteristic that the internal configuration can be flexibly changed and (II) including a network transceiver therein.

There is an FPGA manager as a software-based component for efficiently controlling an FPGA accelerator in a data center (see Non Patent Literature 1). The main purposes of operation of the FPGA manager are to manage a circuit of an FPGA defined on a host device by a client and to control access from an application executed on the host device by the client to a circuit in the FPGA.

The operation of the FPGA manager will be described below with reference to FIG. 6. A client implements a created application program in a host device 1. An FPGA manager 10 implemented on the host device 1 creates bit stream data for defining a function circuit that implements a function to be processed by an FPGA 2 among processing executed by an application execution unit (App). The FPGA manager 10 incorporates a function circuit 20 in the FPGA 2 by transmitting the bit stream data to the FPGA 2.

The host device 1 and the FPGA 2 are connected by PCI Express (PCIe) interface units 11 and 21.

In a case of causing the FPGA 2 to execute processing, the App calls a runtime 12 that is a program for using the function circuit 20. The runtime 12 requests the function circuit 20 in the FPGA 2 to perform processing via the PCIe interface units 11 and 21. The function circuit 20 returns a result of the processing according to the request to the runtime 12. The runtime 12 passes the processing result to the App. Data transfer between the host device 1 and the FPGA 2 is performed by direct memory access (DMA) transfer by a DMA bridge controller 22.

In the conventional FPGA manager, there is an issue that, in a case where there is a function use request from a client connected to a host device via a network, the request needs to be temporarily taken into the host device, and an execution delay increases.

Operation of the FPGA manager in a case where there is a request from a client will be described with reference to FIG. 7. A client terminal 3 connected to the host device 1 via the network needs to access an access acceptance unit 14 outside the FPGA manager 10 via a network interface unit 13 of the host device 1. The access acceptance unit 14 operates asynchronously with the App. For this reason, the App needs to be interrupted from the access acceptance unit 14 at the time of access from the client terminal 3 or polling in which the App makes an inquiry to the access acceptance unit 14 needs to be performed.

In a case where arrival of a function use request from the client terminal 3 is detected by interruption or polling, the App calls the runtime 12 to activate the function circuit 20 in the FPGA 2. The App returns a processing result by the function circuit 20 to the client terminal 3 as a response to the request.

In a case where the function circuit 20 is directly activated from the network and caused to execute processing, the execution path cannot be controlled by the FPGA manager 10. For this reason, flexible circuit rewriting, management of execution authority, and the like are impossible. Therefore, as illustrated in FIG. 7, the access acceptance unit 14 needs to be provided in the host device 1, but an execution delay of processing increases due to the presence of the access acceptance unit 14.

### CITATION LIST

### Non Patent Literature

Non Patent Literature 1: Ting-An Yeh, Hung-Hsin Chen, and Jerry Chou, “KubeShare: a framework to manage GPUs as first-class and shared resources in container cloud”, Proceedings of the 29th International Symposium on High-Performance Parallel and Distributed Computing, 2020.

### SUMMARY

### Technical Problem

Embodiments of the present invention can solve the above issue, and an object of the present invention is to provide an FPGA and an FPGA system capable of executing processing without an unnecessary delay in response to a function use request from a client.

### Solution to Problem

An FPGA of embodiments of the present invention includes a reconfigurable circuit region, an access acceptance unit configured to transfer data to be processed included in a function use request from a client to a function circuit constructed in the circuit region and to return a processing result by this function circuit to the client, and a table in which a function ID that is identification information for each portion of the circuit region, a function name representing a function of the function circuit, and a token that is identification information of the function circuit are stored in association with each other, in which the access acceptance unit identifies a function circuit to which the data to be processed is to be transferred on the basis of a content stored in the table and a function name and a token included in the function use request.

Furthermore, an FPGA system of embodiments of the present invention includes the FPGA and a host device, in which the host device includes an application execution unit configured to, in a case where a resource request for a use application for a function from the client is before the function use request, generate a token allocated to a function for which the use application has been made and transmit a generated token and a function name representing a function for which the use application has been made to the FPGA and the client.

Furthermore, in a configuration example of the FPGA system of embodiments of the present invention, the application execution unit generates the token different for each client.

Furthermore, in a configuration example of the FPGA system of embodiments of the present invention, the FPGA further includes a controller configured to write a function name and a token received from the application execution unit into the table and to return a function ID allocated to a row of a table on which writing has been performed to the application execution unit.

Furthermore, in a configuration example of the FPGA system of embodiments of the present invention, the host device further includes a function circuit management unit configured to transmit bit stream data for reconfiguring the function circuit corresponding to a content stored in the table to the FPGA.

Furthermore, in a configuration example of the FPGA system of embodiments of the present invention, in a case where the resource request is received from the client, the function circuit management unit transmits bit stream data for reconfiguring the function circuit corresponding to a content stored in the table to the FPGA, and, in a case where a resource release notification is received from the client, transmits bit stream data for returning the function circuit to an undefined state to the FPGA.

Furthermore, in a configuration example of the FPGA system of embodiments of the present invention, the FPGA further includes a network interface unit for performing communication with the client via a network, and the access acceptance unit receives a function use request from the client via the network interface unit and returns a processing result by the function circuit to the client via the network interface unit.

Furthermore, in a configuration example of the FPGA system of embodiments of the present invention, the application execution unit transmits a function use request from the client to the FPGA and returns a processing result received from the FPGA to the client, and the access acceptance unit receives the function use request from the application execution unit and returns a processing result by the function circuit to the application execution unit.

### Advantageous Effects of Embodiments of the Invention

According to embodiments of the present invention, by an access acceptance unit being provided in an FPGA, a client can cause a function circuit of the FPGA to process data only by transmitting a function use request to the FPGA without accessing a host device. As a result, the client can obtain a processing result without an unnecessary delay.

### BRIEF DESCRIPTION OF THE DRAWINGS

FIG. 1 is a block diagram illustrating a configuration of an FPGA system according to a first embodiment of the present invention.

FIG. 2 is a block diagram illustrating a configuration of an FPGA system according to a second embodiment of the present invention.

FIG. 3 is a diagram for describing operation of the FPGA system according to the second embodiment of the present invention.

FIG. 4 is a diagram for describing another operation of the FPGA system according to the second embodiment of the present invention.

FIG. 5 is a block diagram illustrating a configuration example of a computer that implements a host device according to first and second embodiments of the present invention.

FIG. 6 is a diagram for describing the operation of a conventional FPGA manager.

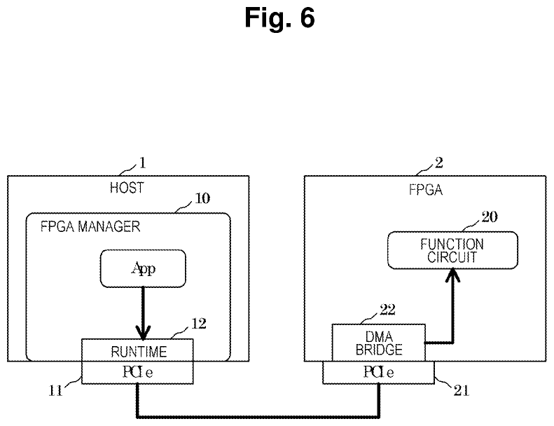

FIG. 7 is a diagram for describing the operation of a conventional FPGA manager in a case where there is a request from a client.

### DETAILED DESCRIPTION OF ILLUSTRATIVE EMBODIMENTS

### First Embodiment

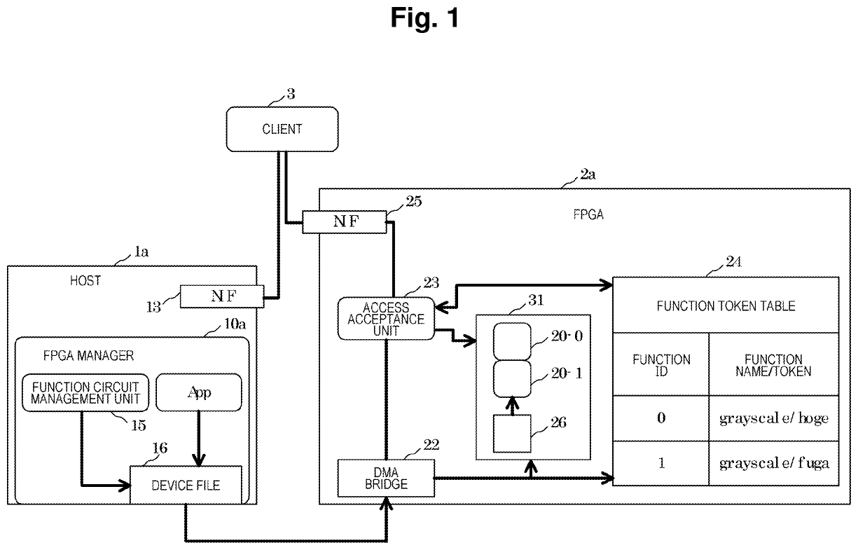

Hereinafter, embodiments of the present invention will be described with reference to the drawings. FIG. 1 is a block diagram illustrating a configuration of an FPGA system according to a first embodiment of the present invention.

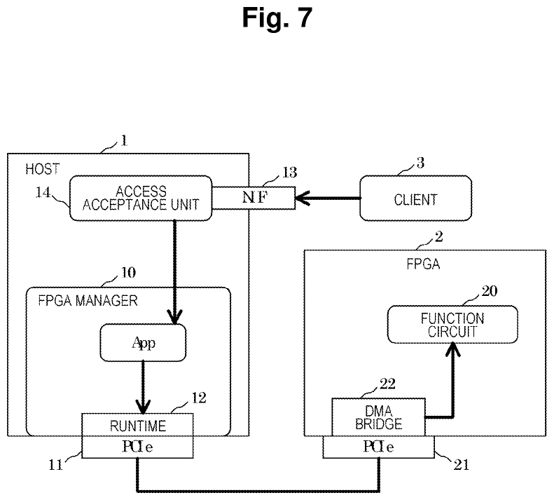

An FPGA 2a of the present embodiment includes an access acceptance unit 23. In the conventional configuration illustrated in FIG. 7, the host device 1 is provided in the access acceptance unit 14 that responds to a function use request from a client. On the other hand, in the present embodiment, the access acceptance unit 23 is implemented on a board of the FPGA 2a.

The access acceptance unit 23 interprets a function use request received from the client terminal 3 via the network interface unit 25 of the FPGA 2a, and it transmits the function use request to an appropriate function circuit 20-0, 20-1 on the basis of a result of the interpretation. The access acceptance unit 23 returns a processing result by the function circuit 20-0, 20-1 to the client terminal 3 of the request source as a response to the function use request.

Furthermore, in a case of receiving a function use request from an application execution unit (App) implemented in the host device 1a, the access acceptance unit 23 similarly interprets the function use request and notifies an appropriate function circuit 20-0, 20-1 of the function use request on the basis of a result of the interpretation. The access acceptance unit 23 returns a processing result by the function circuit 20-0, 20-1 to the App of the request source as a response to the function use request.

An FPGA manager 10a of the host device 1a includes a function circuit management unit 15. In the configuration of the conventional FPGA system illustrated in FIG. 7, the function circuit 20 of the FPGA 2 is caused to execute a part of the processing executed by the App. On the other hand, in the present embodiment, it is also assumed that the client terminal 3 issues a function use request to the function circuit 20-0, 20-1 of the FPGA 2a, and thus the App and function management are separated.

Before execution, the App registers a function to be executed in a function token table 24 of the FPGA 2a.

The function circuit management unit 15 reads bit stream data corresponding to contents registered in the function token table 24 from bit stream data prepared in advance. The function circuit management unit 15 transmits the bit stream data to the FPGA 2a. The bit stream data is written into a configuration memory 26 of the FPGA 2a. As a result, a circuit region 31 of the FPGA 2a is reconfigured, and the function circuit 20-0, 20-1 is constructed in the circuit region 31. A device file 16 will be described in a second embodiment.

The FPGA 2a includes the function token table 24 in which function IDs, function names, and tokens are stored. The function IDs are identification numbers of respective portions of the reconfigurable circuit region 31 of the FPGA 2a. For example, even in a case of function circuits that implement the same function, in a case where writing is performed in different portions of the circuit region 31, different function IDs are allocated.

The function names are names representing functions of function circuits. The function names are managed by the function circuit management unit 15 of the host device 1a. For example, in the example of FIG. 1, the function names are “grayscale”. This example illustrates that the function circuits perform gray-scaling processing on data.

A client designates a function circuit to be used and issues a function use request. A token that is an identifier designating a function circuit is added to the function use request. In the example of FIG. 1, a token of a function circuit having a function ID “0” is “hoge”, and a token of a function circuit having a function ID “1” is “fuga”.

Next, operation of the FPGA system of the present embodiment will be described. A developer of the FPGA system develops a function of the FPGA 2a to be provided to a client and stores bit stream data for defining a function circuit for implementing the function in the function circuit management unit 15 of the host device 1a.

The client that wants to use the function of the FPGA 2a makes a use application for the function to be used to the developer of the FPGA system using the client terminal 3.

The developer that has received the use application activates the App of the host device 1a.

The activated App generates a token to be allocated to a function for which the application has been made by the client and transmits a function name representing the function for which the application has been made by the client and a generated token to the FPGA 2a. Note that the App generates a different token in a case where the client is different even if the function for which the use application has been made is the same.

A DMA bridge controller 22 of the FPGA 2a writes the function name and the token received from the App into the function token table 24. Then, the DMA bridge controller 22 returns a function ID allocated to a row of the function token table 24 in which the function name and the token are written as a response to the App.

The App notifies the function circuit management unit 15 of the function ID received from the FPGA 2a and the function name representing the function for which the application has been made by the client.

The function circuit management unit 15 reads bit stream data corresponding to the function name from bit stream data registered in advance. The function circuit management unit 15 transmits the read bit stream data to the FPGA 2a in order to write the read bit stream data into a region of the configuration memory 26 corresponding to the function ID received from the App.

By the bit stream data being written into the region of the configuration memory 26 corresponding to the function ID via the DMA bridge controller 22 of the FPGA 2a, the circuit region 31 of the FPGA 2a corresponding to the function ID is reconfigured, and a function circuit corresponding to the function ID and the function name is constructed.

The DMA bridge controller 22 returns a circuit writing completion notification as a response to the function circuit management unit 15. The function circuit management unit 15 passes the circuit writing completion notification to the App.

The App that has received the circuit writing completion notification notifies the client terminal 3 of the use application source of resource allocation completion via the network interface unit 13 of the host device 1a. The function name representing the function for which the application has been made by the client and the token allocated to the function for which the application has been made by the client are added to the resource allocation completion notification.

The client that has received the resource allocation completion notification transmits a function use request to the FPGA 2a using the client terminal 3. The function name and the token in the notification from the App and data to be processed are added to the function use request.

The access acceptance unit 23 of the FPGA 2a interprets the function use request received from the client terminal 3 via the network interface unit 25 of the FPGA 2a. The access acceptance unit 23 identifies a function circuit to which the data to be processed included in the function use request is to be transferred on the basis of contents stored in the function token table 24 and the function name and the token included in the function use request. The access acceptance unit 23 transfers the data to be processed to the identified function circuit.

For example, in a case where the function name is “grayscale” and the token is “hoge”, the data to be processed is transferred to the function circuit 20-0 to which the function ID “0” is allocated.

The access acceptance unit 23 returns a processing result by the function circuit 20-0 to the client terminal 3 of the request source as a response to the function use request.

The client terminal 3 that has received the processing result of the data transmits a use completion notification to the App.

The App that has received the use completion notification from the client terminal 3 via the network interface unit 13 of the host device 1a requests the FPGA 2a to delete the function name and the token corresponding to the function that has been used from the function token table 24.

The DMA bridge controller 22 of the FPGA 2a deletes a row including the function name and the token designated from the App from the function token table 24. Then, the DMA bridge controller 22 returns a function ID allocated to the deleted row as a response to the App.

The App notifies the function circuit management unit 15 of the function ID received from the FPGA 2a.

The function circuit management unit 15 transmits bit stream data for deleting a function circuit to the FPGA 2a in order to write the bit stream data into a region of the configuration memory 26 corresponding to the function ID received from the App.

By the bit stream data being written into the region of the configuration memory 26 corresponding to the function ID via the DMA bridge controller 22 of the FPGA 2a, the circuit region 31 of the FPGA 2a corresponding to the function ID returns to an undefined state. This completes the operation of the FPGA system.

In the present embodiment, a client can cause a function circuit of the FPGA 2a to process data without accessing the host device 1a as long as the setting is completed. That is, the client can execute processing without an unnecessary delay.

In the conventional FPGA manager, since an App manages an FPGA, the App needs to be shared by a plurality of clients in a time division manner. On the other hand, in the present embodiment, by a different token being allocated to each client and a different circuit region being used, a plurality of clients can simultaneously use the FPGA 2a, and utilization efficiency in a case where the FPGA 2a is shared by a plurality of clients can be improved.

Improvement of the utilization efficiency of the FPGA 2a leads to improvement of the utilization efficiency of a service provided by the FPGA system, leading to improvement of profitability for a developer that operates the FPGA system.

Furthermore, conventionally, an access acceptance unit is provided in a host device. Therefore, in a case where a function circuit of an FPGA executes processing in response to a function use request from a client, a memory of the host device, a CPU of the host device, and the FPGA are used, and power consumption increases. In the present embodiment, since the access acceptance unit 23 is provided in the FPGA 2a, the host device 1a is not used in a case where a function circuit of the FPGA executes processing in response to a function use request from a client, so that power consumption of the system can be reduced.

Furthermore, in the present embodiment, since a function circuit is kept in an undefined state except in a case where the function circuit of the FPGA 2a executes processing in response to a use application from a client, standby power of the function circuit is not generated, and power consumption of the FPGA 2a can be reduced.

Furthermore, in the present embodiment, since a runtime depending on the vendor is not used, the FPGA system does not depend on a technology of a specific vendor.

### Second Embodiment

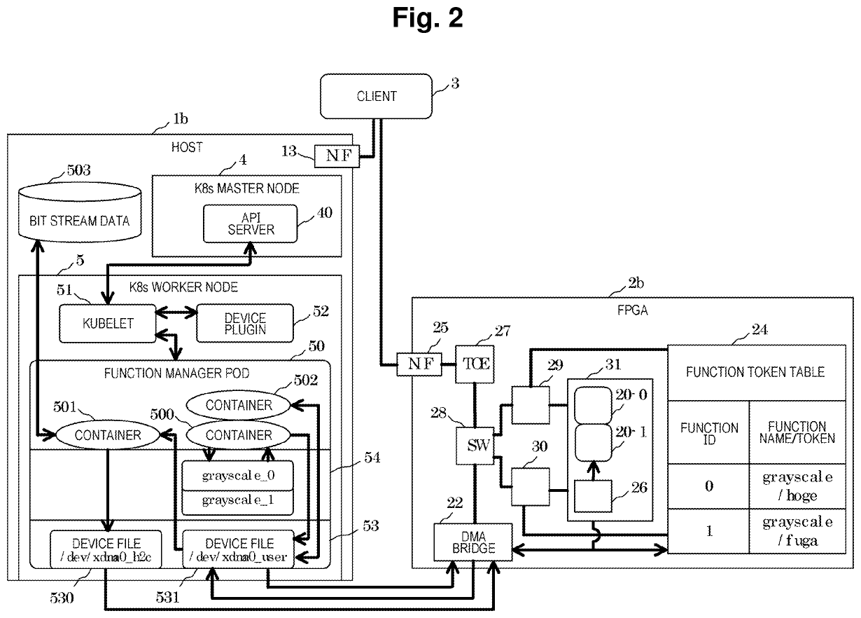

Subsequently, a second embodiment of the present embodiment will be described. FIG. 2 is a block diagram illustrating a configuration of an FPGA system according to the second embodiment of the present invention. In the present embodiment, kubernetes is used as a platform for constructing the FPGA system. Kubernetes is disclosed in, for example, Document ““Kubernetes Document”, Linux Foundation (registered trademark), 2021, accessible at kubernetes.io”. Hereinafter, kubernetes will be abbreviated as K8s.

A K8s master node 4 and a K8s worker node 5 of a host device 1b form the App of the first embodiment.

The K8s master node 4 works on a kubelet 51 of the K8s worker node 5 via an application programming interface (API) server 40.

Specifically, the K8s master node 4 performs communication with a client, management of an access token, and an activation/deletion request of a function manager pod 50.

The K8s worker node 5 includes the function manager pod 50, the kubelet 51 that manages the function manager pod 50, a device plugin 52 in which the function manager pod 50 is written, a device file 53, and a memory region 54.

In FIG. 2, there is one FPGA 2b, but a plurality of function manager pods 50, a plurality of device plugins 52, and a plurality of FPGAs 2b are associated with one K8s worker node 5.

A part of the function manager pod 50 corresponds to the function circuit management unit 15 of the first embodiment. The function manager pod 50 includes a plurality of containers. In the present embodiment, three containers of containers 500 to 502 are included. The function manager pod 50 is activated every use application from a client.

The container 500 writes a function name representing a function for which an application has been made by a client and a token allocated to the function for which the application has been made by the client in a function token table 24 of the FPGA 2b via a DMA bridge controller 22. Furthermore, the container 500 deletes a function name and a token corresponding to a function that has been used from the function token table 24.

The container 501 manages bit stream data 503 for reconfiguring a circuit region 31 of the FPGA 2b, manages a rewriting operation of the circuit region 31, and monitors the function token table 24. The container 501 forms the function circuit management unit 15 of the first embodiment.

The container 502 is a container in which a client on the host device side logs in and controls the FPGA 2b for which setting is completed.

The device file 53 (device file 16 of the first embodiment) is a file serving as an interface with the FPGA 2b connected to the K8s worker node 5. The device file 53 includes a device file 530 for exchanging bit stream data and a device file 531 for controlling the FPGA 2b. The device file 53 exists for each FPGA 2b. A plurality of device files 53 may exist in the function manager pod 50.

In a case of the K8s, information of the configuration in the pod 50 is described in the device plugin 52. The configuration in the pod 50 operates via the kubelet 51 at the time of activation. At this time, resources unique to the FPGA are generated in the memory region 54. In the example of FIG. 2, empty directories are provided as resources. The names of the directories are function name_function ID. Furthermore, although the empty directories are illustrated in FIG. 2, a list in which function names and function IDs are written may be used.

The DMA bridge controller 22 of the FPGA 2b connects the FPGA 2b and the host device 1b. The DMA bridge controller 22 issues a session ID as a side channel.

A TCP/IP offload engine (TOE) 27 of the FPGA 2b manages a transport protocol of a packet transmitted from a network. In the present embodiment, a transmission control protocol/Internet protocol (TCP/IP) will be described as an example of a communication protocol of an Internet layer and a transport layer, but the communication protocol is not limited to a TCP/IP. The TOE 27 issues a session ID as a side channel. The session ID does not overlap between the TOE 27 and the DMA bridge controller 22.

A switch 28 selects the data output direction according to whether input data is a request or a response to a request.

A hypertext transfer protocol (HTTP) parser 29 interprets content of a request and performs processing based on a result of the interpretation on a function circuit or the function token table 24.

An HTTP deparser 30 generates a response message to a request. The TOE 27, the switch 28, the HTTP parser 29, and the HTTP deparser 30 form the access acceptance unit 23 of the first embodiment.

In the present embodiment, an HTTP will be described as an example of a communication protocol of an application layer, but the communication protocol is not limited to an HTTP.

The circuit region 31 is a rewritable region of the FPGA 2b. The function token table 24 is implemented on a dynamic random access memory (DRAM), a block random access memory (BRAM), or a unified random access memory (URAM) of the FPGA 2b. As described in the first embodiment, function IDs, function names, and tokens are stored in the function token table 24. A function implemented by a function circuit for a function ID is uniquely determined. On the other hand, there may be a plurality of tokens for a function ID.

Next, operation of the FPGA system of the present embodiment will be described. The FPGA system includes the following three parties. An administrator of the FPGA system provides all platforms. A developer of the FPGA system develops a service using the FPGA system on a platform and provides the service to clients. The clients use the service provided by the developer. Furthermore, there are two parties of the clients: clients that transmit a function use request to the FPGA 2b via a network; and clients that use the host device 1b.

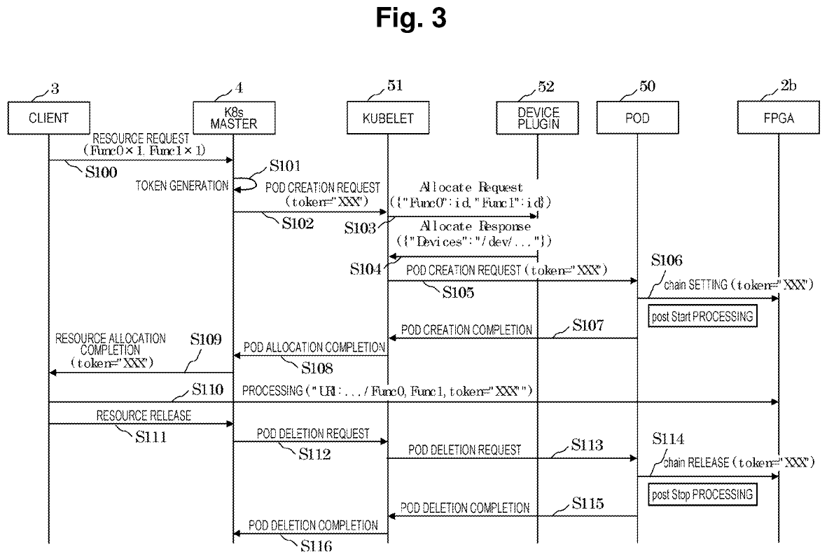

First, operation of the FPGA system in a case where a function use request is transmitted from the client terminal 3 on the network and a processing result is received will be described with reference to FIG. 3.

A developer of the FPGA system develops functions of the FPGA 2b to be provided to clients and stores the bit stream data 503 for defining function circuits for implementing the functions in the host device 1b.

A client that wants to use the functions of the FPGA 2b transmits a resource request for a use application for the functions to be used to the developer of the FPGA system using the client terminal 3 (step S100 in FIG. 3). Func0×1, Func1×1 in FIG. 3 indicates that the client requests to use two gray-scaling functions for data.

The developer that has received the use application activates the App (K8s master node 4, K8s worker node 5) of the host device 1b.

The K8s master node 4 generates tokens to be allocated to the functions for which the application has been made by the client (step S101 in FIG. 3). In the example of FIG. 3, the created tokens are “XXX”. The K8s master node 4 activates the pod 50 according to the device plugin 52 via the kubelet 51 (steps S102 to S105 in FIG. 3).

By the K8s master node 4 passing the resource request from the client to the device plugin 52 via the kubelet 51, the device plugin 52 creates directories in the memory region 54 by the number of functions to be used by the client. The directory names are function name_function ID. In the example of FIG. 2, two directories named grayscale_0 and grayscale_1 are created. Note that the function IDs used for the directory names may be different from function IDs written in the function token table 24 to be described below.

The container 500 of the activated pod 50 reads the directory names from the memory region 54 and checks the function IDs at the end of the directory names. The container 500 transmits the function names and tokens as many as the directory names and the function IDs to the FPGA 2b (step S106 in FIG. 3).

The DMA bridge controller 22 of the FPGA 2b writes the function names and the tokens received from the container 500 into the function token table 24. Then, the DMA bridge controller 22 returns function IDs allocated to rows of the function token table 24 into which the function names and the tokens are written to the container 500.

The container 500 notifies the container 501 of the function IDs received from the FPGA 2b and the function names read from the directory names.

The container 501 reads bit stream data corresponding to the function names from the bit stream data 503 registered in the host device 1b in advance. The container 501 transmits the read bit stream data to the FPGA 2b in order to write the read bit stream data in regions of the configuration memory 26 corresponding to the function IDs received from the container 500.

By the bit stream data being written into the regions of the configuration memory 26 corresponding to the function IDs via the DMA bridge controller 22 of the FPGA 2b, the circuit regions of the FPGA 2b corresponding to the function IDs are reconfigured, and function circuits corresponding to the function IDs and the function names are constructed.

The DMA bridge controller 22 returns a circuit writing completion notification as a response to the pod 50.

The pod 50 that has received the circuit writing completion notification notifies the client terminal 3 of resource allocation completion via the kubelet 51 (steps S107 to S109 in FIG. 3). The function names representing the functions for which the application has been made by the client and the tokens allocated to the functions for which the application has been made by the client are added to the resource allocation completion notification.

The client that has received the resource allocation completion notification transmits a function use request (HTTP request) to the FPGA 2b using the client terminal 3 (step S110 in FIG. 3). An Internet protocol (IP) number and a port number of the network interface unit 25 of the FPGA 2b, a function name and a token in the notification from the pod 50, and data to be processed are added to the function use request.

The TOE 27 of the FPGA 2b performs transport protocol processing on the function use request received via the network interface unit 25.

The switch 28 of the FPGA 2b detects that the data received from the TOE 27 is data from the client on the basis of a session ID issued by the TOE 27. Then, since the data received from the TOE 27 is the function use request, the switch 28 transfers the function use request to the HTTP parser 29.

The HTTP parser 29 interprets content of the function use request. The HTTP parser 29 identifies a function circuit to which the data to be processed included in the function use request is to be transferred on the basis of contents stored in the function token table 24 and the function name and the token included in the function use request. The HTTP parser 29 transfers the data to be processed to the identified function circuit.

For example, in a case where the function name is “grayscale” and the token is “hoge”, the data to be processed is transferred to the function circuit 20-0 to which the function ID “0” is allocated.

The HTTP deparser 30 of the FPGA 2b creates a processing result by the function circuit 20-0 as response data to the function use request.

Since the data received from the HTTP deparser 30 is the response data to the function use request, the switch 28 transfers the response data to the TOE 27.

The TOE 27 assembles response packets from the response data received from the switch 28 and returns the response packets to the client terminal 3 of the request source via the network interface unit 25.

Transmission of a function use request and reception of a processing result are repeatedly performed until processing desired by the client is completed.

Then, after the end of the desired processing, the client transmits a resource release notification to the K8s master node 4 of the host device 1b using the client terminal 3 (step S111 in FIG. 3).

The K8s master node 4 that has received the resource release notification transmits a pod deletion request to the pod 50 via the kubelet 51 (steps S112, S113 in FIG. 3).

The container 500 of the pod 50 that has received the pod deletion request requests the FPGA 2b to delete the function names and the tokens corresponding to the functions that have been used from the function token table 24 (step S114 in FIG. 3).

The DMA bridge controller 22 of the FPGA 2b deletes the rows including the function names and the tokens designated from the container 500 from the function token table 24. Then, the DMA bridge controller 22 returns function IDs allocated to the deleted rows to the container 500.

The container 500 notifies the container 501 of the function IDs received from the FPGA 2b.

The container 501 transmits bit stream data for deleting function circuits to the FPGA 2b in order to write the bit stream data into regions of the configuration memory 26 corresponding to the function IDs received from the container 500.

By the bit stream data being written into the regions of the configuration memory 26 corresponding to the function IDs via the DMA bridge controller 22 of the FPGA 2b, the circuit regions of the FPGA 2b corresponding to the function IDs return to an undefined state.

The container 501 terminates the pod 50 and transmits a pod deletion completion notification to the K8s master node 4 via the kubelet 51 (steps S115, S116 in FIG. 3).

This completes the operation of the FPGA system.

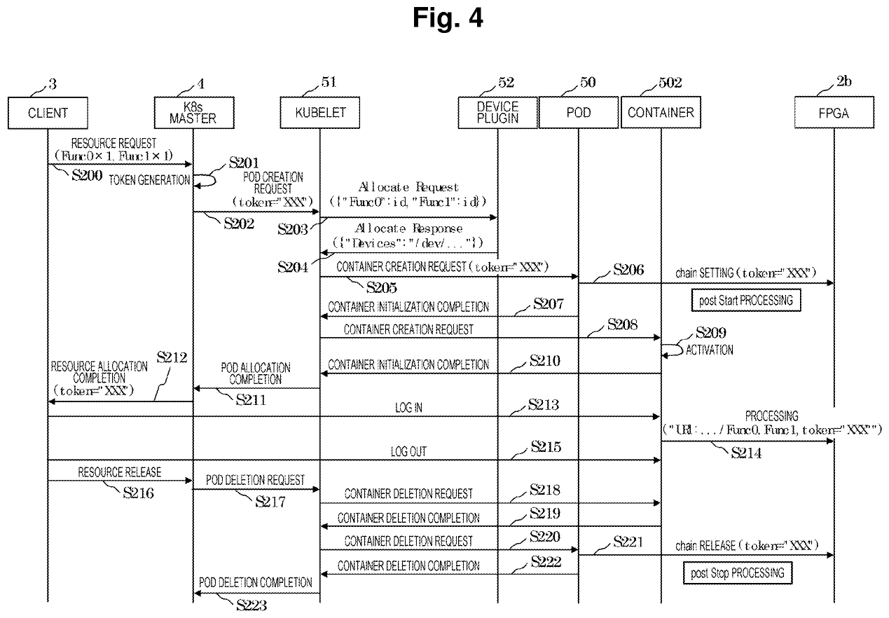

Next, operation of the FPGA system in a case where a function use request is transmitted from the client terminal 3 that has accessed the host device 1b and a processing result is received will be described with reference to FIG. 4.

A developer of the FPGA system develops functions of the FPGA 2b to be provided to clients and stores the bit stream data 503 for defining function circuits for implementing the functions in the host device 1b.

A client that wants to use the functions of the FPGA 2b transmits a resource request for a use application for the functions to be used to the developer of the FPGA system using the client terminal 3 (step S200 in FIG. 4). Func0×1, Func1×1 in FIG. 4 indicates that the client requests to use two gray-scaling functions for data.

The developer that has received the use application activates the App (K8s master node 4, K8s worker node 5) of the host device 1b.

The K8s master node 4 generates tokens to be allocated to the functions for which the application has been made by the client (step S201 in FIG. 4). In the example of FIG. 4, the created tokens are “XXX”. The K8s master node 4 activates the pod 50 according to the device plugin 52 via the kubelet 51 (steps S202 to S205 in FIG. 4).

By the K8s master node 4 passing the resource request from the client to the device plugin 52 via the kubelet 51, the device plugin 52 creates directories in the memory region 54 by the number of functions to be used by the client. The directory names are function name_function ID.

The container 500 of the activated pod 50 reads the directory names from the memory region 54 and checks the function IDs at the end of the directory names. The container 500 transmits the function names and tokens as many as the directory names and the function IDs to the FPGA 2b (step S206 in FIG. 4).

The DMA bridge controller 22 of the FPGA 2b writes the function names and the tokens received from the container 500 into the function token table 24. Then, the DMA bridge controller 22 returns function IDs allocated to rows of the function token table 24 into which the function names and the tokens are written to the container 500.

The container 500 notifies the container 501 of the function IDs received from the FPGA 2b and the function names read from the directory names.

The container 501 reads bit stream data corresponding to the function names from the bit stream data 503 registered in the host device 1b in advance. The container 501 transmits the read bit stream data to the FPGA 2b in order to write the read bit stream data in regions of the configuration memory 26 corresponding to the function IDs received from the container 500.

By the bit stream data being written into the regions of the configuration memory 26 corresponding to the function IDs via the DMA bridge controller 22 of the FPGA 2b, the circuit regions of the FPGA 2b corresponding to the function IDs are reconfigured, and function circuits corresponding to the function IDs and the function names are constructed.

The DMA bridge controller 22 returns a circuit writing completion notification as a response to the pod 50.

The pod 50 that has received the circuit writing completion notification notifies the kubelet 51 of circuit writing completion (step S207 in FIG. 4).

The kubelet 51 creates the container 502 in which the client uses the function circuits (steps S208 to S210 in FIG. 4). After completion of the creation of the container 502, the kubelet 51 notifies the client terminal 3 of resource allocation completion (steps S211, S212 in FIG. 4). The function names representing the functions for which the application has been made by the client and the tokens allocated to the functions for which the application has been made by the client are added to the resource allocation completion notification.

The client that has received the resource allocation completion notification logs in to the host device 1b using the client terminal 3 and transmits a function use request (HTTP request) to the host device 1b (step S213 in FIG. 4). A function name and a token in the notification from the kubelet 51 and data to be processed are added to the function use request.

The container 502 of the host device 1b transmits the function use request from the client to the FPGA 2b (step S214 in FIG. 4).

The DMA bridge controller 22 of the FPGA 2b passes the function use request received from the host device 1b to the switch 28.

The switch 28 of the FPGA 2b detects that the data received from the DMA bridge controller 22 is data from the client on the basis of a session ID issued by the DMA bridge controller 22. Then, since the data received from the DMA bridge controller 22 is the function use request, the switch 28 transfers the function use request to the HTTP parser 29.

The HTTP parser 29 interprets content of the function use request. The HTTP parser 29 identifies a function circuit to which the data to be processed included in the function use request is to be transferred on the basis of contents stored in the function token table 24 and the function name and the token included in the function use request. The HTTP parser 29 transfers the data to be processed to the identified function circuit.

The HTTP deparser 30 of the FPGA 2b creates a processing result by the function circuit as response data to the function use request.

Since the data received from the HTTP deparser 30 is the response data to the function use request, the switch 28 transfers the response data to the DMA bridge controller 22.

The DMA bridge controller 22 returns the response data received from the switch 28 to the host device 1b.

The container 502 of the host device 1b returns the response data received from the FPGA 2b to the client terminal 3 of the request source.

Transmission of a function use request and reception of a processing result are repeatedly performed until processing desired by the client is completed.

After the end of the desired processing, the client transmits a resource release notification to the K8s master node 4 of the host device 1b using the client terminal 3 (step S216 in FIG. 4).

The K8s master node 4 that has received the resource release notification transmits a pod deletion request to the kubelet 51 (step S217 in FIG. 4).

The kubelet 51 transmits a container deletion request to the container 502 of the pod 50 and deletes the container 502 that has been used (steps S218, S219 in FIG. 4). Furthermore, the kubelet 51 transmits the container deletion request to the container 500 of the pod 50 (step S220 in FIG. 4).

The container 500 that has received the container deletion request requests the FPGA 2b to delete the function names and the tokens corresponding to the functions that have been used from the function token table 24 (step S221 in FIG. 4).

The DMA bridge controller 22 of the FPGA 2b deletes the rows including the function names and the tokens designated from the container 500 from the function token table 24. Then, the DMA bridge controller 22 returns function IDs allocated to the deleted rows to the container 500.

The container 500 notifies the container 501 of the function IDs received from the FPGA 2b.

The container 501 transmits bit stream data for deleting function circuits to the FPGA 2b in order to write the bit stream data into regions of the configuration memory 26 corresponding to the function IDs received from the container 500.

By the bit stream data being written into the regions of the configuration memory 26 corresponding to the function IDs via the DMA bridge controller 22 of the FPGA 2b, the circuit regions of the FPGA 2b corresponding to the function IDs return to an undefined state.

The container 501 terminates the pod 50 and transmits a pod deletion completion notification to the K8s master node 4 via the kubelet 51 (steps S222, S223 in FIG. 4).

This completes the operation of the FPGA system.

As described in FIG. 3, in the present embodiment, a client can cause a function circuit of the FPGA 2b to process data without accessing the host device 1b as long as the setting is completed. Conventionally, a delay of accessing the host device is large, but in the present embodiment, a client can execute processing without an unnecessary delay.

In the conventional FPGA manager, since an App manages an FPGA, the App needs to be shared by a plurality of clients in a time division manner. On the other hand, in the present embodiment, by a different token being allocated to each client and a different circuit region being used, a plurality of clients can simultaneously use the FPGA 2b, and utilization efficiency in a case where the FPGA 2b is shared by a plurality of clients can be improved.

Improvement of the utilization efficiency of the FPGA 2b leads to improvement of the utilization efficiency of a service provided by the FPGA system, leading to improvement of profitability for a developer that operates the FPGA system.

Furthermore, conventionally, an access acceptance unit is provided in a host device. Therefore, in a case where a function circuit of an FPGA executes processing in response to a function use request from a client, a memory of the host device, a CPU of the host device, and the FPGA are used, and power consumption increases.

In the present embodiment, since the access acceptance unit (TOE 27, switch 28, HTTP parser 29, and HTTP deparser 30) is provided in the FPGA 2b, the host device 1b is not used in a case where a function circuit of the FPGA 2b executes processing in response to a function use request from a client, so that power consumption of the system can be reduced. The host device 1b only manages the function token table 24, and does not need to perform data transfer in response to a function use request.

Furthermore, in the present embodiment, since a function circuit is kept in an undefined state except in a case where the function circuit of the FPGA 2b executes processing in response to a use application from a client, standby power of the function circuit is not generated, and power consumption of the FPGA 2b can be reduced.

Furthermore, conventionally, even if the network is a broadband, the throughput of the service is restricted unless the PCIe interface unit is a broadband. Therefore, investment in both the network and PCIe is required. On the other hand, in the present embodiment, in a case of the operation described with reference to FIG. 3, since the throughput of the service is determined by the bandwidth of the network, the investment efficiency can be improved.

Furthermore, in the present embodiment, since a runtime depending on the vendor is not used, the FPGA system does not depend on a technology of a specific vendor.

Note that, although kubernetes is used as a platform for constructing the FPGA system in the present embodiment, it goes without saying that other tools may be used.

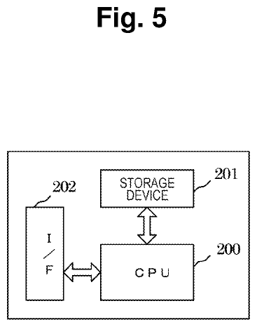

The host devices 1a and 1b described in the first and second embodiments can each be implemented by a computer including a CPU, a storage device, and an interface, and a program for controlling these hardware resources. A configuration example of this computer is illustrated in FIG. 5. The computer includes a CPU 200, a storage device 201, and an interface device (I/F) 202.

For example, hardware or the like of the network interface unit 13 is connected to the I/F 202. In such a computer, a program for implementing the FPGA system of embodiments of the present invention is stored in the storage device 201. The CPU 200 executes the processing described in the first and second embodiments according to the program stored in the storage device 201.

### INDUSTRIAL APPLICABILITY

The present embodiments can be applied to a system using an FPGA.

Reference Signs List

| | |
|---|---|
| 1a, 1b | Host device |
| 2a, 2b | FPGA |
| 3 | Client terminal |
| 4 | K8s master node |
| 5 | K8s worker node |
| 10a | FPGA manager |
| 13, 25 | Network interface unit |
| 15 | Function circuit management unit |
| 20-0, 20-1 | Function circuit |
| 22 | DMA bridge controller |
| 23 | Access acceptance unit |
| 24 | Function token table |
| 26 | Configuration memory |
| 27 | TOE |
| 28 | Switch |
| 29 | HTTP parser |
| 30 | HTTP deparser |
| 31 | Circuit region |
| 40 | API server |
| 50 | Function manager pod |
| 51 | Kubelet |
| 52 | Device plugin |
| 53, 530, 531 | Device file |
| 54 | Memory region |
| 500 to 502 | Container |
| App | Application execution unit |

1.-8. (canceled)

9. A field programmable gate array (FPGA) comprising:
a reconfigurable circuit region;
an access acceptance circuit configured to transfer data to be processed included in a function use request from a client to a function circuit constructed in the reconfigurable circuit region and to return a processing result by the function circuit to the client; and
a table in which a function ID that is identification information for each portion of the reconfigurable circuit region, a function name representing a function of the function circuit, and a token that is identification information of the function circuit are stored in association with each other, wherein the access acceptance circuit identifies the function circuit to which the data to be processed is to be transferred based on a content stored in the table and the function name and the token included in the function use request.

10. The FPGA according to claim 9, wherein:
the FPGA further comprises a network interface circuit configured to perform communication with the client via a network; and
the access acceptance circuit is configured to receive the function use request from the client via the network interface circuit and to return a processing result by the function circuit to the client via the network interface circuit.

11. The FPGA according to claim 9, wherein the access acceptance circuit is mounted on a board of the FPGA.

12. A field programmable gate array (FPGA) system comprising:
an FPGA comprising:
a reconfigurable circuit region;
an access acceptance circuit configured to transfer data to be processed included in a function use request from a client to a function circuit constructed in the reconfigurable circuit region and to return a processing result by the function circuit to the client; and
a table in which a function ID that is identification information for each portion of the reconfigurable circuit region, a function name representing a function of the function circuit, and a token that is identification information of the function circuit are stored in association with each other, wherein the access acceptance circuit identifies the function circuit to which the data to be processed is to be transferred based on a content stored in the table and the function name and the token included in the function use request and
a host device comprising one or more processors and a storage device storing a program to be executed by the one or more processors, wherein, in a case in which a resource request for a use application for a function from the client is before the function use request, the program includes instructions to generate the token allocated to the function for which the use application has been made and transmit the generated token and the function name representing the function for which the use application has been made to the FPGA and the client.

13. The FPGA system according to claim 12, wherein the program further includes instructions to generate the token different for each client.

14. The FPGA system according to claim 13, wherein the FPGA further comprises a controller configured to write the function name and the token received from the host device into the table and to return the function ID allocated to a row of the table on which writing has been performed to the host device.

15. The FPGA system according to claim 13, wherein the program further includes instructions to transmit bit stream data for reconfiguring the function circuit corresponding to the content stored in the table to the FPGA.

16. The FPGA system according to claim 15, wherein, in a case in which a resource release notification is received from the client, the program further includes instructions to transmit bit stream data for returning the function circuit to an undefined state to the FPGA.

17. The FPGA system according to claim 16, wherein:
the FPGA further comprises a network interface circuit configured to perform communication with the client via a network; and
the access acceptance circuit is configured to receive the function use request from the client via the network interface circuit and return a processing result by the function circuit to the client via the network interface circuit.

18. The FPGA system according to claim 17, wherein:
the program further includes instructions to transmit the function use request from the client to the FPGA and to return a processing result received from the FPGA to the client; and
the access acceptance circuit is configured to receive the function use request from the host device and to return a processing result by the function circuit to the host device.

19. The FPGA system according to claim 12, wherein the FPGA further comprises a controller configured to write the function name and the token received from the host device into the table and to return the function ID allocated to a row of the table on which writing has been performed to the host device.

20. The FPGA system according to claim 12, wherein:
the FPGA further comprises a network interface circuit configured to perform communication with the client via a network; and
the access acceptance circuit is configured to receive the function use request from the client via the network interface circuit and return a processing result by the function circuit to the client via the network interface circuit.

21. The FPGA system according to claim 12, wherein:
the program further includes instructions to transmit the function use request from the client to the FPGA and to return a processing result received from the FPGA to the client; and
the access acceptance circuit is configured to receive the function use request from the host device and to return a processing result by the function circuit to the host device.

22. A field programmable gate array (FPGA) system comprising:
an FPGA comprising:
a reconfigurable circuit region;
an access acceptance circuit configured to transfer data to be processed included in a function use request from a client to a function circuit constructed in the reconfigurable circuit region and to return a processing result by the function circuit to the client; and
a table in which a function ID that is identification information for each portion of the reconfigurable circuit region, a function name representing a function of the function circuit, and a token that is identification information of the function circuit are stored in association with each other, wherein the access acceptance circuit is configured to identify the function circuit to which the data to be processed is to be transferred based on a content stored in the table and the function name and the token included in the function use request; and
a host device, wherein, in a case in which a resource request for a use application for a function from the client is before the function use request, the host device comprises an application execution circuit configured to generate the token allocated to the function for which the use application has been made and transmit the generated token and the function name representing the function for which the use application has been made to the FPGA and the client.

23. The FPGA system according to claim 22, wherein the application execution circuit is configured to generate the token different for each client.

24. The FPGA system according to claim 22, wherein the FPGA further comprises a controller configured to write the function name and the token received from the application execution circuit into the table and to return the function ID allocated to a row of the table on which writing has been performed to the application execution circuit.

25. The FPGA system according to claim 24, wherein the host device further comprises a function circuit management circuit configured to transmit bit stream data for reconfiguring the function circuit corresponding to the content stored in the table to the FPGA.

26. The FPGA system according to claim 25, wherein, in a case in which the resource request is received from the client, the function circuit management circuit is configured to transmit bit stream data for reconfiguring the function circuit corresponding to the content stored in the table to the FPGA, and, in a case in which a resource release notification is received from the client, to transmit bit stream data for returning the function circuit to an undefined state to the FPGA.

27. The FPGA system according to claim 26, wherein:
the FPGA further comprises a network interface circuit configured to perform communication with the client via a network; and
the access acceptance circuit is configured to receive the function use request from the client via the network interface circuit and to return a processing result by the function circuit to the client via the network interface circuit.

28. The FPGA system according to claim 26, wherein:
the application execution circuit is configured to transmit the function use request from the client to the FPGA and to return a processing result received from the FPGA to the client; and
the access acceptance circuit is configured to receive the function use request from the application execution circuit and to return a processing result by the function circuit to the application execution circuit.
